(19) United States
(12) Patent Application Publication
(10) Pub. No.: US 2025/0264365 A1
(43) Pub. Date: Aug. 21, 2025

(54) System for non-invasively determining a temperature of a conductor of an electric cable

(71) Applicant: NEXANS, Courbevoie (FR)

(72) Inventor: Raphaël GUFFOND, LYON (FR)

(21) Appl. No.: 19/039,095

(22) Filed: Jan. 28, 2025

(30) Foreign Application Priority Data
Feb. 21, 2024 (FR) 2401717

(51) Int. Cl. G01K 7/42; G01K 1/143; G01R 15/18

(52) U.S. Cl. CPC G01K 7/427; G01K 1/143; G01R 15/181

(57) ABSTRACT

A determination system (100) for non-invasively determining a temperature of a conductor of an electric cable includes an electric cable (10) with at least one electrical conductor (12) and at least one layer of material (14, 16) surrounding the at least one conductor. The at least one layer having a layer thermal resistance T₁. At least one temperature sensor (20) is placed on an outer surface (18) of the at least one layer of material for measuring a peripheral temperature Θ_{b1} on the outer surface of the at least one layer of material. A determination unit (22) is configured to determine a conductor temperature Θ_{cond} as a function of the measured peripheral temperature Θ_{b1}, the layer thermal resistance T₁ and the heat flux W_{c} generated by the flow of an electrical current in the electrical conductor.

### RELATED APPLICATION

This application claims the benefit of French Patent Application No. 24 01717, filed on Feb. 17, 2024, the entirety of which is incorporated by reference.

### TECHNICAL FIELD

The present invention relates to a system for determining the temperature of an electrical conductor of an electric cable.

More specifically, the invention relates to a non-invasive determination system.

### TECHNOLOGICAL BACKGROUND

During the testing or use stage of an electric cable, it is important to know the temperature of the conductor of the electric cable so as to be able to monitor the correct operation of this same cable and for sizing it correctly.

One difficulty is that placing a temperature sensor directly in the vicinity of the conductor means there is a hole or a space within the cable, and this can generate electrical arcs within this space.

To overcome this difficulty, it is known practice to connect a portion of the electric cable to a test loop formed by a cable of the same type as the electric cable. No voltage is applied in the test loop and a temperature sensor is placed in contact with the conductor. This makes it possible to monitor the variation in temperature of the conductor of the test loop so as to estimate the temperature of the conductor of the portion of electric cable in which a current flows. The drawback of this method is that it can only be performed in a test phase and not on an electric cable installed in situ.

Another method consists in placing an optical fibre inside an electric cable along the electrical conductor while this electric cable is being manufactured. This optical fibre makes it possible to measure the temperature of the conductor. The drawback of this method is that it is invasive because the presence of the optical fibre requires an adaptation of the electric cable. Moreover, the optical fibre must be inserted over the entire length of the cable, and this entails high costs.

There is thus a need for a system for non-invasively determining a temperature of a conductor of an electric cable.

### SUMMARY OF THE INVENTION

To this end, the invention provides a system for non-invasively determining a temperature of a conductor of an electric cable, comprising:
an electric cable comprising at least one electrical conductor and at least one layer of material surrounding said at least one conductor, said at least one layer having a layer thermal resistance T₁,
at least one temperature sensor placed on an outer surface of said at least one layer of material for measuring a peripheral temperature Θ_{b1} on the outer surface of said at least one layer of material,
a determination unit configured to determine a conductor temperature Θ_{cond} as a function of the measured peripheral temperature Θb₁ and the layer thermal resistance T₁.

The conductor temperature Θ_{cond} is determined here by means of a physical model utilizing the measured peripheral temperature Θb₁ and the layer thermal resistance T₁.

The utilization of this physical model makes it possible to dispense with the utilization of a temperature inside the electric cable, i.e. measured via a component placed in the vicinity of the conductor, or more generally inside the outer sheath of the electric cable.

The physical model utilized makes it possible to estimate the conductor temperature Θ_{cond} by means of the measured peripheral temperature Θb₁ and the layer thermal resistance T₁.

According to one embodiment of the determination system, it also comprises:
at least one additional layer of material placed around said at least one layer of material and covering said at least one temperature sensor, said additional layer of material having an additional thermal resistance T_{b},
at least one additional temperature sensor placed on an outer surface of said additional layer of material for measuring an additional peripheral temperature Θ_{b2} on the outer surface of said at least one additional layer of material.

According to one embodiment of the determination system, said additional layer of material extends around said at least one layer of material only over a portion of the length of the electric cable.

According to one embodiment of the determination system, said at least one additional layer of material comprises:
a first additional-layer portion having a first additional thermal resistance T_{b}, and
a second additional-layer portion having a second additional thermal resistance T′_{b}, the first additional thermal resistance T_{b} and second additional thermal resistance T′_{b} being different,
   and wherein said at least one additional temperature sensor comprises:
at least one first additional temperature sensor placed on an outer surface of the first additional-layer portion for measuring a first additional peripheral temperature Θ_{b2},
at least one second additional temperature sensor placed on an outer surface of the second additional-layer portion for measuring a second additional peripheral temperature Θ′_{b2},
   the determination unit being configured to determine the conductor temperature Θ_{cond} also as a function of the first additional thermal resistance T_{b} and the second additional thermal resistance T′_{b} and also of the first additional peripheral temperature Θ_{b2} and the second additional peripheral temperature Θ′_{b2}.

According to one embodiment of the determination system, said at least one first and at least one second additional layer are placed over different angular sectors around the electrical conductor.

Said at least one first and at least one second additional layer may overlap at least partially.

According to one embodiment of the determination system, said at least one first and at least one second additional layer together form a layer extending continuously around the electrical conductor in a plane perpendicular to the longitudinal axis of extent of the electrical conductor.

According to one embodiment of the determination system, said at least one temperature sensor comprises:
at least one first sensor placed on the outer surface of said at least one layer of material, between said outer surface and the first additional-layer portion, for measuring a peripheral temperature Θ_{b1} on the outer surface of said at least one layer of material,
at least one second sensor placed on the outer surface of said at least one layer of material, between said outer surface and the second additional-layer portion, for measuring a peripheral temperature Θ′_{b1} on the outer surface of said at least one layer of material.

According to one embodiment of the determination system, the determination unit is configured to determine the conductor temperature Θ_{cond} on the basis of the following equation:

$${θ}_{c onducteur} = \frac{( {θ}_{b 1} {T}_{b} - {θ}_{b 1}^{′} {T}_{b}^{′} ) \times ( ( {θ}_{b 1} - {θ}_{b 2} ) )}{{T}_{b} ( {θ}_{b 1}^{′} - {θ}_{b 2}^{′} ) - {T}_{b}^{′} ( {θ}_{b 1} - {θ}_{b 2} )}$$

where T₁ is the thermal resistance of said at least one layer of material,
T_{b} is the first additional thermal resistance of the first additional layer of material,
T′_{b} is the second additional thermal resistance of the second additional layer of material,
Θ_{b1} is the peripheral temperature measured by said at least one first temperature sensor,
Θ_{b2} is the additional peripheral temperature measured by said at least one first additional temperature sensor,
Θ′_{b1} is the peripheral temperature measured by said at least one second temperature sensor,
Θ′_{b2} is the additional peripheral temperature measured by said at least one second additional temperature sensor.

According to one embodiment of the determination system, the first and second additional-layer portions are made of a different material.

According to one embodiment of the determination system, the first and second additional-layer portions have a different thickness, considered perpendicularly in relation to a longitudinal axis of extent of the electric cable.

According to one embodiment of the determination system, said at least one layer of material comprises an outer sheath forming said outer surface, said at least one temperature sensor being placed on said outer sheath.

According to one embodiment of the determination system, the determination unit is configured to determine a conductor temperature Θ_{cond} as a function of the measured peripheral temperature Θ_{b1} and the layer thermal resistance T₁ and the heat flux W_{c} generated by the flow of an electrical current in the electrical conductor.

According to one embodiment of the determination system, the determination unit is configured to determine the conductor temperature Θ_{cond} as a function of the heat flux W_{c} generated by the flow of an electrical current in the electrical conductor, on the basis of the following equation:

$${Θ}_{cond} = {Θ}_{b 1} {W}_{c} ⋆ T$$

The determination unit may be placed in the vicinity of or at a distance from the electric cable.

According to one embodiment of the determination system, said at least one layer of material comprises an outer sheath forming said outer surface, said at least one temperature sensor being placed on said outer sheath.

According to one embodiment of the determination system, it also comprises a device for measuring the electrical intensity I_{cond} of an electrical current flowing in said at least one electrical conductor, the determination unit being configured to determine said conductor temperature Θ_{cond} also as a function of this electrical intensity I_{cond}.

According to one embodiment of the determination system, the measuring device is a non-invasive device, in particular of the Rogowski coil type.

According to one embodiment of the determination system, the conductor temperature Θ_{cond} is determined as follows:

$${Θ}_{cond} = {Θ}_{b 1} + {R}_{c}^{⋆} {I}_{cond}^{⋆} {T}_{1}$$

where R_{c} is the electrical resistance of the conductor.

According to one embodiment of the determination system, it also comprises:
an additional layer of material placed around said at least one layer of material and covering said at least one temperature sensor, said additional layer of material having an additional thermal resistance T_{b},
at least one additional temperature sensor placed on an outer surface of said additional layer of material for measuring an additional peripheral temperature Θ_{b2} on the outer surface of said at least one additional layer of material.

According to one embodiment of the determination system, said additional layer of material extends around said at least one layer of material only over a portion of the length of the electric cable.

According to one embodiment of the determination system, the determination unit is configured to determine the conductor temperature Θ_{cond} on the basis of the following equation:

$${θ}_{c o n d} = {θ}_{b 1} + \frac{( {θ}_{b 1} - {θ}_{b 2} )}{{T}_{b}} \times {T}_{1}$$

where Θ_{b1} is the peripheral temperature measured by said at least one temperature sensor,
Θ_{b2} is the additional peripheral temperature measured by said at least one additional temperature sensor,
T_{b} is the additional thermal resistance of the additional layer of material,
T₁ is the thermal resistance of said at least one layer of material.

According to one embodiment of the determination system, the determination unit is configured to determine the conductor temperature Θ_{cond} also as a function of a heating W_{d} originating from a dielectric loss in said at least one layer of material.

According to one embodiment of the determination system, the determination unit is configured to determine the conductor temperature Θ_{cond} on the basis of the following equation:

$${θ}_{c o n d} = {θ}_{b 1} + {T}_{1} \times ( {W}_{c} - \frac{{W}_{d}}{2} )$$

where W_{d} is the heating originating from a dielectric loss in said at least one layer of material.

According to one embodiment of the determination system, the determination unit is configured to determine the conductor temperature Θ_{cond} on the basis of the following equation:

$${θ}_{c o n d} = {θ}_{b 1} + {T}_{1} \times ( \frac{{θ}_{b 1} - {θ}_{b 2}}{{T}_{b}} - \frac{{W}_{d}}{2} )$$

where W_{d} is the heating originating from a dielectric loss in said at least one layer of material.

According to one embodiment of the determination system, it additionally comprises a determination module comprising one or more of the following: said at least one temperature sensor and the determination unit, the module being configured to be removably mounted on the electric cable.

According to one embodiment of the determination system, said at least one additional layer of material and said at least one additional temperature sensor are supported by the determination module.

This determination module is for example removable from the electric cable so as to take a localized measurement on the electric cable at certain points. This module is for example a measurement accessory.

The determination module has a dimension along the longitudinal axis such that it extends only over a portion of the length of the electric cable.

### BRIEF DESCRIPTION OF THE FIGURES

The following description provided with reference to the appended drawings, which are given by way of non-limiting example, will make it easy to understand what the invention consists of and how it may be implemented. In the appended figures:

FIG. 1 shows a sectional view of an electric cable in a first configuration comprising an electrical conductor and at least one layer of material, the electric cable belonging to a determination system;

FIG. 2 shows a sectional view of the electric cable in FIG. 1 comprising a plurality of sensors on an outer surface of said at least one layer of material;

FIG. 3 shows a diagram of a first modelling of the electric cable, according to a first mode of determination comprising a determination of the electrical intensity of the electrical current flowing in the electrical conductor;

FIG. 4 shows a sectional view of the electric cable in FIG. 1 according to a second mode of determination in which the determination system comprises an additional layer of material around the electric cable and a plurality of additional sensors placed on an outer surface of this additional layer of material;

FIG. 5 shows a diagram of a second modelling of the electric cable according to the second mode of determination;

FIG. 6 shows a third modelling of the electric cable in which the dielectric losses in said at least one layer of material are taken into account, according to the first mode of determination;

FIG. 7 shows a fourth modelling of the electric cable in which the dielectric losses in said at least one layer of material are taken into account, according to the second mode of determination;

FIG. 8 shows a sectional view of the electric cable in a second configuration comprising an electrical conductor, one or more layers of material surrounding the electrical conductor and a shield surrounding said layers of material;

FIG. 9 shows a fifth modelling of the electric cable in which the dielectric losses in said at least one layer of material, as well as the dielectric losses in the shield, are taken into account;

FIG. 10 shows a sixth modelling of the electric cable for determining the conductor temperature Θ_{cond} independently of the environment;

FIG. 11 shows a perspective view of one embodiment of the determination system in FIG. 1 comprising a determination module mounted on the electric cable, the determination module comprising a temperature sensor and/or a temperature unit;

FIG. 12 represents a view in section of the electrical cable from FIG. 4 in a second determination mode in which the determination system comprises an additional layer of material formed of first and second additional layer portions and a plurality of additional sensors disposed on an external surface of each of the first and second additional layer of material portions;

FIG. 13 represents a diagram of a seventh model of the electrical cable utilising the first additional layer portion from FIG. 12;

FIG. 14 represents a diagram of the seventh model of the electrical cable utilising the second additional layer portion from FIG. 12;

FIG. 15 represents an equation for determining the conductor temperature using the seventh model;

FIG. 16 represents a diagram of an eighth model of the electrical cable utilising the first additional layer portion from FIG. 12;

FIG. 17 represents a diagram of the eighth model of the electrical cable utilising the second additional layer portion from FIG. 12;

FIG. 18 represents an equation for determining the conductor temperature utilising the eighth model.

### DESCRIPTION OF EMBODIMENT(S)

For the sake of clarity, the same references denoting the same elements according to the prior art and according to the invention are used throughout the figures.

The concept of the invention is described more fully below with reference to the attached drawings, which show embodiments of the concept of the invention. In the drawings, the size and the relative sizes of the elements may be exaggerated for the sake of clarity. Similar numbers refer to similar elements throughout the drawings. However, this concept of the invention can be implemented in many different forms and should not be interpreted as being limited to the embodiments set out here. Instead, these embodiments are provided so that this description is comprehensive, and communicate the scope of the concept of the invention to those skilled in the art.

Reference throughout the specification to “an/one embodiment” means that a particular function, structure or feature described in relation to one embodiment is included in at least one embodiment of the present invention. The occurrence of the expression “in an/one embodiment” in various places throughout the specification thus does not necessarily refer to the same embodiment. Furthermore, the particular functions, structures or features can be combined in any suitable manner in one or more embodiments. In addition, the term “comprising/having/including” does not rule out other elements or steps.

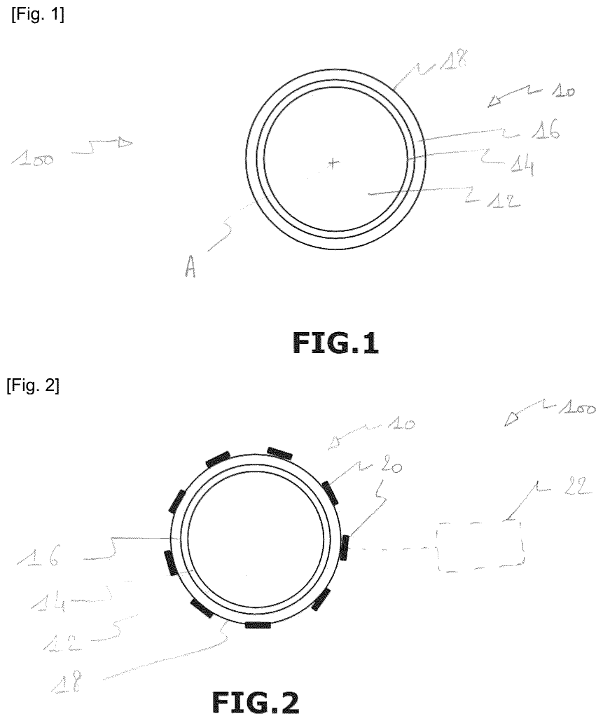

With reference to FIG. 1, an electric cable 10 comprises an electrical conductor 12, a first layer of material 14 around the electrical conductor 12 and a second layer of material 16 around the first layer of material 14.

The electrical conductor 12 extends along a longitudinal axis A.

The first layer of material 14 and second layer of material 16 extend along the longitudinal axis A, around the electrical conductor 12.

The first layer of material 14 is for example a layer made of an electrically insulating material. The first layer of material 14 can thus be regarded as an insulating layer.

The second layer of material 16 in this case forms an outer layer of the electric cable 10. The second layer of material 16 forms an outer surface 18 of the electric cable 10.

The second layer of material 16 is for example an outer sheath.

More generally, the electric cable 10 may have one or more layers of material surrounding the electrical conductor 12. The electric cable 10 may in particular comprise one or more of the following: a shield, a semi-conducting layer, an insulating layer, an outer sheath.

In a preferred configuration, the electric cable 10 comprises, placed around the conductor in the following order from the centre to the periphery: a semi-conducting layer, an insulating layer, a shield and an outer sheath. This configuration corresponds for example to an electric cable configured for a medium-voltage (between 1 and 52 kV) network.

With reference to FIG. 2, a determination system 100 comprises the electric cable 10, at least one temperature sensor 20 and a determination unit 22.

The determination system 100 may comprise a plurality of temperature sensors 20 distributed around the longitudinal axis A in a single plane transverse to this longitudinal axis A. In the example in FIG. 2, the determination system 100 comprises nine temperature sensors 20.

The one or more temperature sensors 20 are configured to measure a peripheral temperature Θ_{b1}. In this configuration, in which the temperature sensors 20 are placed on the outer surface 18 of the electric cable, the peripheral temperature Θ_{b1} corresponds to the surface temperature of the electric cable 10.

The one or more temperature sensors 20 are connected to the determination unit 22 so as to communicate the peripheral temperature Θ_{b1} to this determination unit 22.

With preference, the temperature sensors 20 are evenly distributed around the longitudinal axis A. The determination system 100 can provide one or more temperature sensors 20 distributed furthermore along the longitudinal axis A so as to measure the peripheral temperature Θ_{b1} at various locations along the electric cable 10.

This determination unit 22 is configured to determine the conductor temperature Θ_{cond}, i.e. the temperature of the electrical conductor 12.

This determination is made non-invasively and non-destructively. Thus, no component is inserted beneath the layers of material or in the vicinity of the electrical conductor 12 to determine its conductor temperature Θ_{cond}. Moreover, no layer of material of the electric cable 10 is damaged or pierced to make this determination. No third component is integrated in the manufacture of the electric cable 10, such as an optical fibre or a sensor in one of the layers of the electric cable 10 or between these layers of material.

“Non-invasive” or “non-destructive” is understood more generally to mean that the initial structure of the cable is not modified. This initial structure of the cable corresponds to the structure of the cable without a unit for determining the temperature or, more generally, a device for determining the temperature of the electrical conductor.

This makes it possible to determine the conductor temperature on an existing electric cable, for example one already installed in situ, without needing to damage it or insert any measuring tool therein.

The addition of measuring components or additional layers of material is considered not to be invasive or destructive in this case.

The determination unit 22 utilizes a physical model for determining the conductor temperature Θ_{cond} as a function of the peripheral temperature Θₑ₁ measured by the one or more temperature sensors 20.

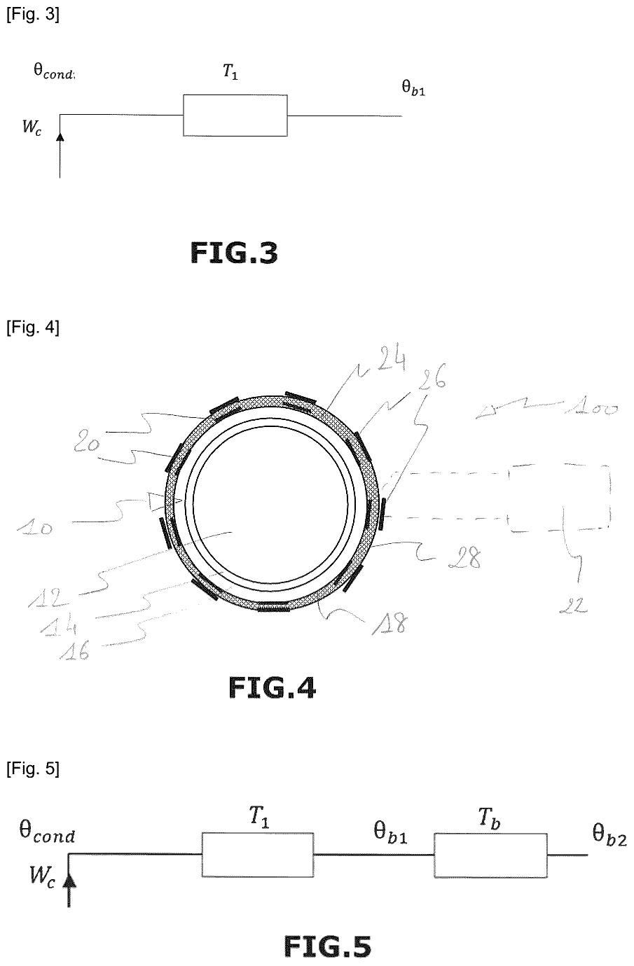

With reference to FIG. 3, the diffusion of heat through the electric cable 10 is shown in the form of a diagram for illustrating the physical model utilized by the determination unit 22.

This physical model is based on the fact that the diffusion of heat through the layers of an electric cable behaves very much like the flow of a current within an electric circuit which has an electrical resistance.

Thus, the physical model establishes a relationship between the thermal resistance T₁ of said at least one layer of material. The thermal resistance T₁ may correspond to the thermal resistance of one or more of the layers of material. In the example in FIG. 2, the thermal resistance T₁ represents the thermal resistance of the assembly of the first layer of material 14 and second layer of material 16. For this physical model, the first layer of material 14 and second layer of material 16 thus form one and the same layer of material having a layer thermal resistance, denoted T₁.

The flow of the current inside the conductor generates heating which induces a heat flux W_{c}.

In this physical model, the voltage difference ΔU across the terminals of an electrical resistance is close to a temperature difference ΔΘ between the inner and outer surfaces of said at least one layer of material (i.e. across the terminals of this layer of material).

During use of the electric cable 10, the temperatures across the terminals of the thermal resistance T₁ are the conductor temperature Θ_{cond} on one side and the peripheral temperature Θ_{b1} on the other side. As a result, the temperature difference ΔΘ is expressed as follows: ΔΘ=Θ_{cond}−Θ_{b1}.

According to this physical model, a mathematical relationship is established between the heat flux W_{c}, the thermal resistance T₁ and the temperature difference ΔΘ across the terminals of this thermal resistance. This relationship is as follows:

$$Δθ = {T}_{1} * {W}_{c}$$

where
ΔΘ is the temperature difference ΔΘ between the inner and outer surfaces of said at least one layer of material,
T₁ is the thermal resistance of said at least one layer of material,
W_{c} is the heat flux generated by the heating of the conductor.

The conductor temperature Θ_{cond} can thus be expressed as follows:

$${θ}_{cond} = {θ}_{b 1} + {W}_{c} * {T}_{1}$$

where
Θ_{cond} is the conductor temperature,
Θ_{b1} is the peripheral temperature.

The thermal resistance T₁ of said at least one layer of material is determined as follows:

$${T}_{1} = \frac{{ρ}_{T}}{2 \times π} ln ( 1 + 2 * \frac{{t}_{1}}{{d}_{c}} )$$

where
β_{T} IS the thermal conductivity of said at least one layer of material,
d_{c} is the inside diameter of said at least one layer of material,
t₁ is the thickness of said at least one layer of material.

The physical model comprises two modes for determining the conductor temperature Θ_{cond}.

In the first mode of determination, the determination system 100 comprises a device for measuring the electrical intensity I_{cond} of an electrical current flowing in said at least one electrical conductor 12.

The measuring device is a non-invasive device, in particular of the Rogowski coil type.

In the second mode of determination, the determination system 100 comprises at least one additional layer of material 24 and at least one additional temperature sensor 26.

This second mode of determination makes it possible to do away with utilizing the electrical intensity I_{cond} of the current flowing in the conductor.

Said at least one additional layer of material 24 is placed around said at least one layer of material. The one or more additional layers of material 24 cover said at least one temperature sensor 22, as can be seen in FIG. 4.

These two modes of determination can be utilized to determine the conductor temperature Θ_{cond} according to different modellings of an electric cable 10. These different modellings can involve different assumptions (e.g. taking into account or not taking into account dielectric losses) or different configurations of the electric cable 10.

The determination unit 22 is configured to implement the first mode of determination and/or the second mode of determination. The determination unit 22 is configured to determine the conductor temperature Θ_{cond} according to one or more modellings, in particular one or more of the modellings set out below.

Electric Cable without Shield, and without Taking into Account Dielectric Losses

The determination unit 22 is configured to determine the conductor temperature Θ_{cond} according to a first modelling and a second modelling, which are illustrated in FIGS. 3 and 5, respectively.

More specifically, the determination unit 22 is configured to determine the conductor temperature Θ_{cond} according to the first modelling by means of the first mode of determination. The determination unit 22 is configured to determine the conductor temperature Θ_{cond} according to the second modelling by means of the second mode of determination.

In the first and second modellings, the dielectric losses in said at least one layer of material are not taken into account or are regarded as minimal.

In these first and second modellings, the electric cable 10 does not have a shield.

The first modelling applies to the electric cable 10 comprising an electrical conductor 12 and one or more layers of material surrounding the electrical conductor 12. One or more temperature sensors 20 are placed on the outer surface 18 of said at least one layer of material.

The electric cable 10 according to FIG. 2 is an example compatible with this first modelling.

As indicated above, the conductor temperature Θ_{cond} can be expressed as follows:

$${θ}_{cond} = {θ}_{b 1} + {W}_{c} * {T}_{1}$$

where
Θ_{cond} is the conductor temperature,
Θ_{b1} is the peripheral temperature,
T₁ is the thermal resistance of said at least one layer of material,
W_{c} is the heat flux generated by the heating of the conductor.

According to the first mode of determination, the heat flux W_{c} owing to the heating of the electrical conductor 12 is expressed as follows:

$${W}_{c} = {R}_{c} * {I}_{cond}^{2}$$

where R_{c} is the electrical resistance of the electrical conductor,
I_{cond} is the intensity of the current flowing along the electrical conductor.

The conductor temperature Θ_{cond} according to the first mode of determination, i.e. as a function of the intensity of the electrical conductor, is thus expressed as follows:

$${θ}_{cond} = {θ}_{b 1} + {R}_{c} * {I}_{cond}^{2} * {T}_{1}$$

The electrical resistance R_{c} of the electrical conductor is expressed as follows:

$${R}_{c} = {R}_{0} \times ( 1 + {α}_{20} \times ( {Θ}_{cond} - 20 ) ) \times ( 1 + {y}_{s} + {y}_{p} )$$

where
R₀ is the DC resistance of the conductor at 20° C., in ohms,
Yₛ is the skin effect factor, which is dimensionless,
Yₚ is the proximity effect factor, which is dimensionless,
α₂₀ is the coefficient of electrical resistivity, in K⁻¹ (i.e. per kelvin).

The parameters R₀, Yₛ, Yₚ and α₂₀ are values linked to the structure and the type of the electrical conductor.

The conductor temperature Θ_{cond} can thus be expressed as follows:

$${Θ}_{cond} = \frac{{Θ}_{b 1} - {R}_{0}^{2} \times {T}_{1} \times ( 1 - 20 \times {α}_{20} )}{1 - {R}_{0} \times {I}_{cond}^{2} \times {α}_{20} \times {T}_{1}}$$

According to the second mode of determination, i.e. without the conductor intensity I_{cond}, the determination unit 100 comprises an additional structure illustrated in FIG. 4. Thus, the determination system 100 comprises at least one additional layer of material 24 and at least one additional temperature sensor 26.

Said at least one additional layer of material 24 has an additional thermal resistance T_{b}.

Said at least one additional layer of material 24 is for example at least one electrically insulating layer.

The material of said at least one additional layer of material 24 preferably has a thermal resistance between 0.001 m²·K/W and 0.1 m²·K/W. Within this thermal resistance range, said at least one layer of material 24 makes it possible to avoid the overheating of the conductor while permitting a temperature difference that is large enough to be measured.

Said at least one additional temperature sensor 26 makes it possible to measure an additional peripheral temperature Θ_{b2} on the outer surface 28 of said at least one additional layer of material 24.

The determination system 100 may comprise a plurality of additional temperature sensors 26 distributed around the longitudinal axis A in a single plane transverse to the longitudinal axis A. In the example in FIG. 4, the determination system 100 comprises nine additional temperature sensors 26.

The one or more additional temperature sensors 26 are connected to the determination unit 22 so as to communicate the additional peripheral temperature Θ_{b2} to this determination unit 22.

With preference, the additional temperature sensors 26 are evenly distributed around the longitudinal axis A. The determination system 100 can provide one or more additional temperature sensors 26 distributed furthermore along the longitudinal axis A so as to measure the additional peripheral temperature Θ_{b2} at various locations along the electric cable 10.

With preference, the number and/or the angular position and/or the longitudinal position of the temperature sensors 20 are respectively identical to the number and/or the angular position and/or the longitudinal position of the additional temperature sensors 26.

The electric cable 10 equipped with said at least one additional layer of material 24 and said at least one additional temperature sensor 26 is modelled by a second modelling in FIG. 5. Said at least one additional layer of material 24 is regarded as a resistance of value T_{b} connected in series with the resistance of value T₁ corresponding to said at least one layer of material.

According to this second mode of determination, the heat flux Wo is expressed as follows:

$${W}_{c} = \frac{( {Θ}_{b 1} - {Θ}_{b 2} )}{{T}_{b}}$$

The conductor temperature can thus be expressed as follows:

$${θ}_{cond} = {θ}_{b 1} + \frac{( {θ}_{b 1} - {θ}_{b 2} )}{{T}_{b}} \times {T}_{1}$$

The conductor temperature Θ_{cond} can thus be determined without requiring the value for the intensity of the current flowing in the electrical conductor 12. This determination is made possible by the addition of an additional layer and an additional sensor.

Electric Cable without Shield, and Taking into Account Dielectric Losses

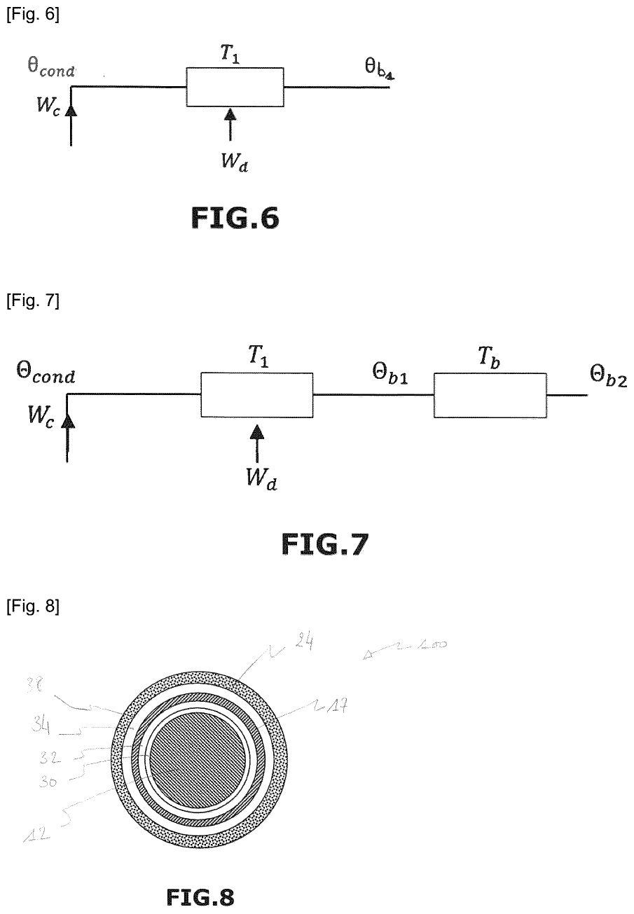

The determination unit 22 is configured to determine the conductor temperature Θ_{cond} according to a third and a fourth modelling which are illustrated in FIGS. 6 and 7, respectively.

More specifically, the determination unit 22 is configured to determine the conductor temperature Θ_{cond} according to the third modelling by means of the first mode of determination. The determination unit 22 is configured to determine the conductor temperature Θ_{cond} according to the fourth modelling by means of the second mode of determination.

In the third and fourth modellings, the dielectric losses in said at least one layer of material are taken into account.

In these third and fourth modellings, the electric cable 10 does not have a shield.

In these third and fourth modellings, the dielectric losses in said at least one layer of material are regarded as a loss heat flux W_{d} at the resistance of value T₁ corresponding to said at least one layer of material. This loss heat flux W_{d} can be seen in FIGS. 6 and 7.

The third modelling applies to the electric cable 10 comprising an electrical conductor 12 and one or more layers of material surrounding the electrical conductor 12. One or more temperature sensors 20 are placed on the outer surface 18 of said at least one layer of material.

The electric cable 10 according to FIG. 2 is an example compatible with this third modelling.

According to the first mode of determination, the conductor temperature Θ_{cond} can be expressed as follows as a function of the electrical intensity I_{cond}:

$${θ}_{cond} = {θ}_{b 1} + {T}_{1} \times ( {W}_{c} - \frac{{W}_{d}}{2} )$$

This conductor temperature Θ_{cond} may also be expressed as follows by deconstructing R_{c} as described above:

$${θ}_{cond} = \frac{{θ}_{b 1} - ( {R}_{0} {I}_{cond}^{2} ) {T}_{1} ( 1 - 20 \times {α}_{20} ) + \frac{1}{2} {T}_{1} {W}_{d}}{1 - {R}_{0} {I}_{cond}^{2} {α}_{20} {T}_{1}}$$

According to the second mode of determination, i.e. without the conductor intensity I_{cond}, the determination unit 100 comprises an additional structure as illustrated in FIG. 4. Thus, the determination system 100 comprises at least one additional layer of material 24 and at least one additional temperature sensor 26.

The electric cable 10 equipped with said at least one additional layer of material 24 and said at least one additional temperature sensor 26 is modelled by a fourth modelling in FIG. 7.

Said at least one additional layer of material 24 is regarded as a resistance of value T_{b} connected in series with the resistance of value T₁ corresponding to said at least one layer of material.

According to this second mode of determination, the conductor temperature Θ_{cond} is expressed as follows:

$${θ}_{cond} = {θ}_{b 1} + {T}_{1} \times ( \frac{( {θ}_{b 1} - {θ}_{b 2} )}{{T}_{b}} - \frac{{W}_{d}}{2} )$$

The above equation is obtained by considering the following equations:

$${θ}_{cond} = {θ}_{b 1} + {T}_{1} \times ( {W}_{c} + \frac{{W}_{d}}{2} ) \\ and \\ {θ}_{b 1} = {θ}_{b 2} + {T}_{b} \times ( {W}_{d} + {W}_{c} )$$

The loss heat flux W_{d} is determined as a function of the voltage applied to the electrical conductor 12, the frequency of the voltage applied to the electrical conductor 12, and the dielectric characteristics of said at least one layer of material.

Electric Cable with Shield, and Taking into Account Dielectric Losses

The determination unit 22 is also configured to determine the conductor temperature Θ_{cond} in a configuration of the electric cable 10 comprising a shield 17.

As illustrated in FIG. 8, the electric cable 10 comprises an electrical conductor 12, one or more layers of material surrounding the electrical conductor 12, and a shield 17 surrounding said layers of material.

Said layers of material are for example a dielectric layer 30 surrounding the electrical conductor 12 and an insulating layer 32 placed between the dielectric layer 30 and the shield 17.

The electric cable 10 also comprises an outer layer 34, for example an outer sheath, defining an outer surface 38 of the outer layer 34. The outer layer 34 may comprise a plurality of layers of material.

The outer layer 34 has a thermal resistance T₃.

One or more temperature sensors 20 are placed on the outer surface 38 of the outer layer 34.

Losses in the shield 17 are modelled by a shield heat flux Wₛ. These losses are caused by Joule heating in the shield 17.

The determination of the shield heat flux Wₛ requires an invasive measurement on the electric cable 10. To make expressing the conductor temperature Θ_{cond} as a function of the heat flux Wₛ redundant, it is proposed in this case to combine the first and second modes of determination seen above. In other words, it is provided in this case to express the conductor temperature Θ_{cond} as a function of the intensity I_{cond} of the voltage flowing in the electrical conductor 12 and to use an additional structure comprising at least one additional layer of material 24 and at least one additional temperature sensor 26, as can be seen in FIG. 8.

Said at least one additional layer of material 24 has a thermal resistance T_{b}.

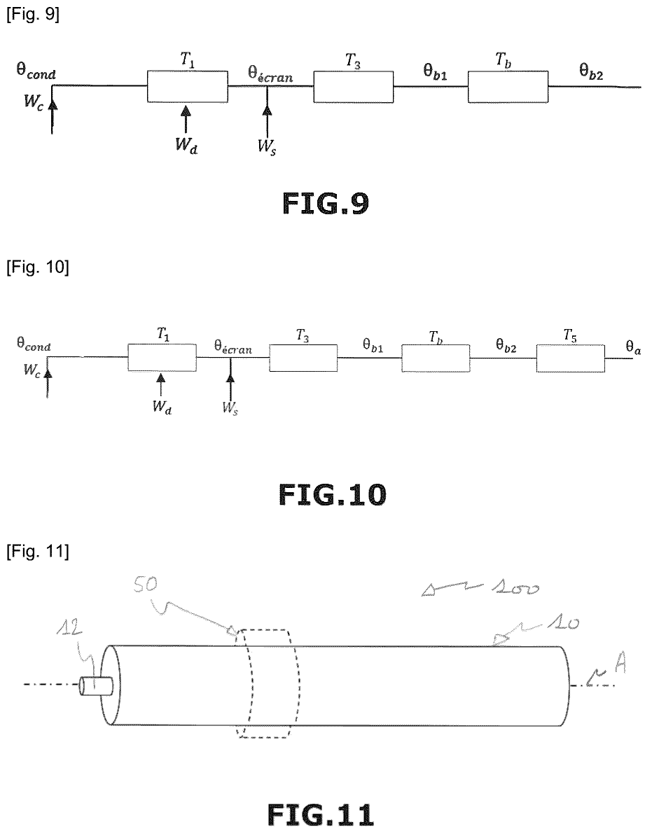

A fifth modelling is illustrated in FIG. 9, taking into account the shield losses (heat flux Wₛ) and the dielectric losses in said at least one layer (heat flux W_{d}) and comprising three resistances connected in series for modelling the thermal resistances of said at least one layer of material (T₁), of the outer sheath 34 (T₃) and of said at least one additional layer of material 24 (T_{b}).

In this fifth modelling, the conductor temperature Θ_{cond} is expressed as follows:

$${θ}_{cond} = \frac{{θ}_{b 1} + {T}_{3} \frac{{Δθ}_{b}}{{T}_{b}} + \frac{1}{2} {T}_{1} {W}_{d} - ( {R}_{0} {I}^{2} ) {T}_{1} ( 1 - 20 \times {α}_{20} )}{1 - {R}_{0} {I}_{cond}^{2} {α}_{20} {T}_{1}}$$

where Θ_{b1} is the peripheral temperature measured by said at least one temperature sensor 20,
Θ_{b2} is the additional peripheral temperature measured by said at least one additional temperature sensor 26,
ΔΘ is the temperature difference Θ_{b1}−Θ_{b2},
T₁ is the thermal resistance of said at least one layer of material,
T_{b} is the thermal resistance of said at least one additional layer of material 24,
T₃ is the thermal resistance of the outer layer 34,
R₀ is the DC resistance of the conductor at 20° C., in ohms,
Yₛ is the skin effect factor, which is dimensionless,
Yₚ is the proximity effect factor, which is dimensionless,
α₂₀ is the coefficient of electrical resistivity, in K⁻¹ (i.e. per kelvin).

The determination unit 22 is thus capable of determining the conductor temperature Θ_{cond} independently of the shield heat flux Wₛ.

This expression of the conductor temperature Θ_{cond} is obtained by considering that:

$${θ}_{cond} = {θ}_{surf} + n ( {W}_{c} + {W}_{s} + {W}_{d} ) {T}_{3} + ( {W}_{c} + \frac{{W}_{d}}{2} ) {T}_{1} \\ n ( {W}_{c} + {W}_{s} + {W}_{d} ) = \frac{{Δθ}_{b}}{{T}_{b}} \\ {θ}_{conducteur} = {θ}_{b 1} + {T}_{3} \frac{{Δθ}_{b}}{{T}_{b}} + ( {W}_{c} + \frac{{W}_{d}}{2} ) {T}_{1}$$

where Θ_{surf} is the peripheral temperature on the outer surface of the electric cable 10, and
n is the number of electrical conductors 12.

As set out in detail above, the thermal resistance T₁ is determined as follows:

$${T}_{1} = \frac{{ρ}_{T}}{2 \times π} ln ( 1 + 2 * \frac{{t}_{1}}{{d}_{c}} )$$

The thermal resistance T₃ of the outer layer 34 is determined as follows:

$${T}_{3} = \frac{{ρ}_{T}}{2 \times π} ln ( 1 + 2 * \frac{{t}_{3}}{{D}_{a}} )$$

where
t₃ is the thickness of the outer layer 34,
Dₐ is the inside diameter of the outer layer 34.

According to a sixth modelling illustrated in FIG. 10, the determination unit is also configured to determine the conductor temperature Θ_{cond} independently of the environment, in particular of the temperature of this environment.

This sixth modelling applies to the same configuration of electric cable 10 as the fifth modelling. In other words, the sixth modelling applies to an electric cable of the type in FIG. 8 with an additional structure and a shield 17.

Depending on the environment, the heat will be discharged from the electric cable 10 to a greater or lesser extent. The environment is modelled by a layer of material which has a certain thermal resistance T₅ and a temperature Θₐ corresponding to the ambient temperature of the environment.

The conductor temperature Θ_{cond} can be expressed in this way:

$${θ}_{cond} = {θ}_{a} + ( {W}_{c} + \frac{{W}_{d}}{2} ) {T}_{1} + n ( {W}_{c} + {W}_{d} + {W}_{s} ) {T}_{3} + n ( {W}_{c} + {W}_{d} + {W}_{s} ) {T}_{b} + n ( {W}_{c} + {W}_{d} + {W}_{s} ) {T}_{5}$$

The temperature difference Θ_{b1}−Θ_{b2} in the temperature on either side of the additional layer of material 24 makes it possible to express the conductor temperature Θ_{cond} as follows:

$${θ}_{cond} = {θ}_{b 1} + ( {W}_{c} + \frac{{W}_{d}}{2} ) {T}_{1} + n ( {W}_{c} + {W}_{d} + {W}_{s} ) {T}_{b} \\ and \\ {θ}_{b 1} - {θ}_{b 2} = n ( {W}_{c} + {W}_{d} + {W}_{s} ) {T}_{b}$$

The conductor temperature Θ_{cond} can thus be determined by the determination unit 22 independently of the environment.

With reference to FIG. 11, the determination system 100 may comprise a determination module 50 which accommodates one or more of the following: said at least one temperature sensor 20.

The determination unit 22 is preferably supported by the determination module 50. If the determination unit is offset from the determination module 50, the determination module 50 is configured to communicate information, in particular sensor measurements, to the determination unit 22.

This determination module 50 is for example removable from the electric cable 10 so as to take a localized measurement on the electric cable 10 at certain points. This module is for example a portable measurement accessory.

The determination module 50 has a dimension along the longitudinal axis A such that it extends only over a portion of the length of the electric cable 10.

The determination module 50 may also comprise the additional structure. In other words, the determination module 50 may also comprise said at least one additional layer of material 24 and said at least one additional temperature sensor 26.

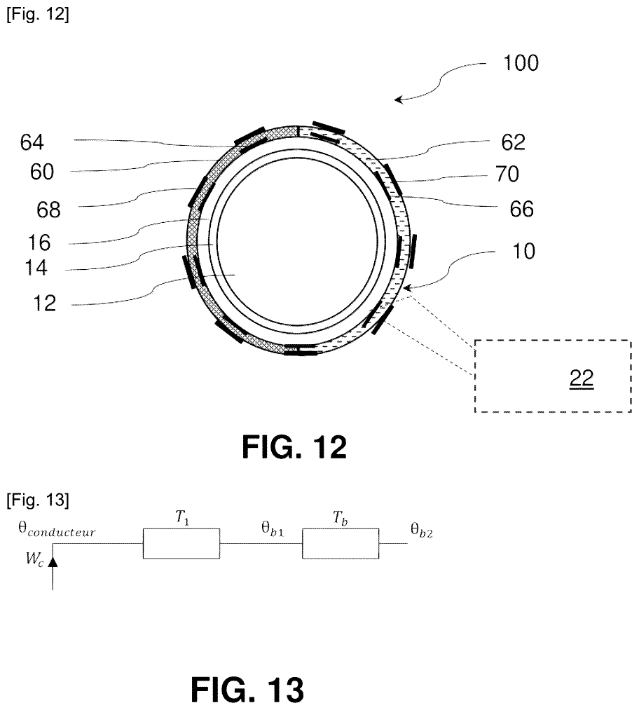

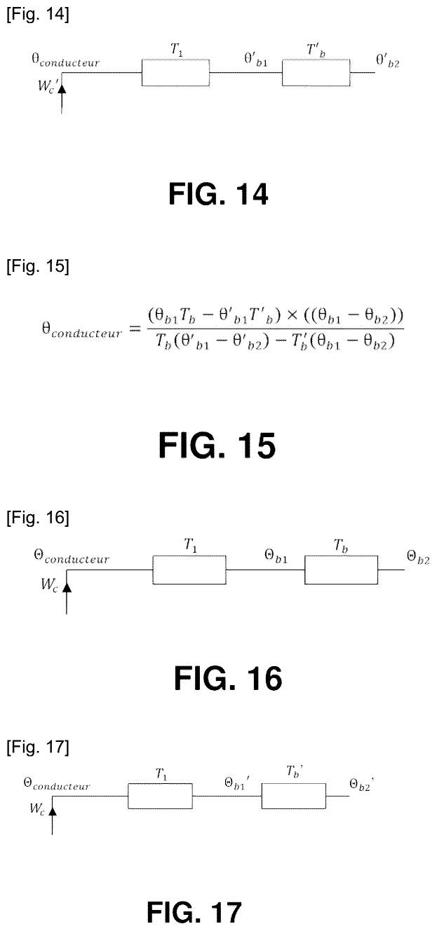

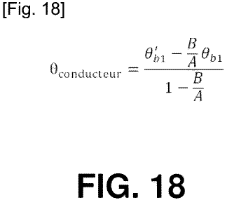

In connection with FIGS. 12 to 18, the determination unit 22 is also configured to determine the conductor temperature Θ_{cond} according to a seventh and an eighth modelling.

In seventh and eighth modellings, the determination unit 22 is configured to determine the conductor temperature Θ_{cond} without needing to determine the heat flux W_{c} generated by the flow of an electrical current in the electrical conductor.

For these seventh and eighth modellings, the determination system 100 is similar to that in FIG. 4, the difference being that said at least one additional layer 24 comprises a first additional-layer portion 60 and a second additional-layer portion 62, as illustrated in FIG. 12.

The first additional-layer portion 60 has a first additional thermal resistance T_{b}. The second additional-layer portion 62 has a second additional thermal resistance T′_{b}. The first additional thermal resistance T_{b} and second additional thermal resistance T′_{b} are different.

This difference between the first additional thermal resistance T_{b} and second additional thermal resistance T′_{b} can be obtained by utilizing a different material and/or one or more different geometric characteristics between the first additional-layer portion 60 and the second additional-layer portion 62. One example of a different geometric characteristic is a different thickness, considered along an axis perpendicular to the longitudinal axis of extent A of the electrical conductor.

This difference between the first additional thermal resistance T_{b} and the second additional thermal resistance T′_{b} makes it possible to construct two different equations with the conductor temperature Θ_{cond} as the unknown. It is thus no longer necessary to know the heat flux W_{c}.

A plurality of first temperature sensors 64 are placed on the outer surface 18 of said at least one layer of material, between said outer surface 18 and the first additional-layer portion 60. The plurality of first temperature sensors 64 makes it possible to measure a first peripheral temperature Θ_{b1} on the outer surface 18 of said at least one layer of material.

A plurality of second temperature sensors 66 is placed on the outer surface 18 of said at least one layer of material, between said outer surface 18 and the second additional-layer portion 62. The plurality of second temperature sensors 66 makes it possible to measure a second peripheral temperature Θ′_{b1} on the outer surface 18 of said at least one layer of material.

A plurality of first additional temperature sensors 68 are placed on an outer surface of the first additional-layer portion 60 for measuring a first additional peripheral temperature Θ_{b2}.

A plurality of second additional temperature sensors are placed on an outer surface of the second additional-layer portion for measuring a second additional peripheral temperature Θ′_{b2}.

The determination unit 22 is configured to determine the conductor temperature Θ_{cond} also as a function of the first additional thermal resistance T_{b} and of the second additional thermal resistance T′_{b}, as well as of the first additional peripheral temperature Θ_{b2} and the second additional peripheral temperature Θ′_{b2}.

Electric Cable without Shield, without Taking into Account Dielectric Losses

The seventh modelling is illustrated in FIGS. 13 to 15.

In this seventh modelling, the conductor temperature Θ_{cond} is expressed as follows:

$${θ}_{conducteur} = \frac{( {θ}_{b 1} {T}_{b} - {θ}_{b 1}^{′} {T}_{b}^{′} ) \times ( ( {θ}_{b 1} - {θ}_{b 2} ) )}{{T}_{b} ( {θ}_{b 1}^{′} - {θ}_{b 2}^{′} ) - {T}_{b}^{′} ( {θ}_{b 1} - {θ}_{b 2} )}$$

This equation is obtained via the following developments:

$$\frac{( {θ}_{conducteur} - {θ}_{b 1} )}{{T}_{1}} = \frac{( {θ}_{b 1} - {θ}_{b 2} )}{{T}_{b}} \\ \frac{( {θ}_{conducteur} - {θ}_{b 1}^{′} )}{{T}_{1}} = \frac{( {θ}_{b 1}^{′′′} - {θ}_{b 2}^{′} )}{{T}_{b}^{′}} \\ ( {θ}_{conducteur} - {θ}_{b 1} ) \frac{{T}_{b}}{( {θ}_{b 1} - {θ}_{b 2} )} = ( {θ}_{conducteur} - {θ}_{b 1}^{′} ) \frac{{T}_{b}^{′}}{( {θ}_{b 1}^{′′′} - {θ}_{b 2}^{′} )} \\ {θ}_{conducteur} = \frac{{θ}_{b 1} {T}_{b} - {θ}_{b 1}^{′} {T}_{b}^{′}}{( {θ}_{b 1}^{′} - {θ}_{b 2}^{′} )} / ( \frac{{T}_{b}}{( {θ}_{b 1} - {θ}_{b 2} )} - \frac{{T}_{b}^{′}}{( {θ}_{b 1}^{′} - {θ}_{b 2}^{′} )} )$$

Electric Cable without Shield, Taking into Account Dielectric Losses

The eighth modelling is illustrated in FIGS. 16 to 18.

In this eighth modelling, the conductor temperature Θ_{cond} is expressed as follows:

$${θ}_{conducteur} = \frac{{θ}_{b 1}^{′} - \frac{B}{A} {θ}_{b 1}}{1 - \frac{B}{A}}$$

This equation is obtained via the following developments:

$${θ}_{conducteur} = {θ}_{b 1} + {T}_{1} \times ( \frac{( {θ}_{b 1} - {θ}_{b 2} )}{{T}_{b}} - \frac{{W}_{d}}{2} ) \\ {θ}_{conducteur} = {θ}_{b 1}^{′} + {T}_{1} \times ( \frac{( {θ}_{b 1}^{′} - {θ}_{b 2}^{′} )}{{T}_{b}^{′}} - \frac{{W}_{d}}{2} ) \\ A = ( \frac{( {θ}_{b 1} - {θ}_{b 2} )}{{T}_{b}} - \frac{{W}_{d}}{2} ) \\ B = ( \frac{( {θ}_{b 1}^{′} - {θ}_{b 2}^{′} )}{{T}_{b}^{′}} - \frac{{W}_{d}}{2} )$$

where θ_{b1}′ is the first peripheral temperature on the outer surface 18 of said at least one layer of material,
Θ_{b2}′ is the second additional peripheral temperature,
T_{b}′ is the second additional thermal resistance.

1. A determination system for non-invasively determining a temperature of a conductor of an electric cable, comprising:
an electric cable comprising at least one electrical conductor and at least one layer of material surrounding said at least one conductor, said at least one layer having a layer thermal resistance T₁,
at least one temperature sensor placed on an outer surface of said at least one layer of material for measuring a peripheral temperature Θ_{b1} on the outer surface of said at least one layer of material,
a determination unit configured to determine a conductor temperature Θ_{cond} as a function of the measured peripheral temperature Θ_{b1} and the layer thermal resistance T₁.

2. The determination system according to claim 1, further comprising:
at least one additional layer of material placed around said at least one layer of material and covering said at least one temperature sensor, said additional layer of material having an additional thermal resistance T_{b},
at least one additional temperature sensor placed on an outer surface of said additional layer of material for measuring an additional peripheral temperature Θ_{b2} on the outer surface of said at least one additional layer of material.

3. The determination system according to claim 2, wherein said additional layer of material extends around said at least one layer of material only over a portion of the length of the electric cable.

4. The determination system according to claim 2, wherein said at least one additional layer of material comprises:
a first additional-layer portion having a first additional thermal resistance T_{b}, and
a second additional-layer portion having a second additional thermal resistance T′_{b}, the first additional thermal resistance T_{b} and second additional thermal resistance T′_{b} being different,
and wherein said at least one additional temperature sensor comprises:
at least one first additional temperature sensor placed on an outer surface of the first additional-layer portion for measuring a first additional peripheral temperature Θ_{b2},
at least one second additional temperature sensor placed on an outer surface of the second additional-layer portion for measuring a second additional peripheral temperature Θ′_{b2},
the determination unit being configured to determine the conductor temperature Θ_{cond} also as a function of the first additional thermal resistance T_{b} and the second additional thermal resistance T′_{b} and also of the first additional peripheral temperature Θ_{b2} and the second additional peripheral temperature Θ′_{b2}.

5. The determination system according to claim 4, wherein said at least one first and at least one second additional layer are placed over different angular sectors around the electrical conductor.

6. The determination system according to claim 5, wherein said at least one temperature sensor comprises:
at least one first sensor placed on the outer surface of said at least one layer of material, between said outer surface and the first additional-layer portion, for measuring a peripheral temperature Θ_{b1} on the outer surface of said at least one layer of material,
at least one second sensor placed on the outer surface of said at least one layer of material, between said outer surface and the second additional-layer portion, for measuring a peripheral temperature Θ′_{b1} on the outer surface of said at least one layer of material.

7. The determination system according to claim 6, wherein the determination unit is configured to determine the conductor temperature Θ_{cond} on the basis of the following equation:
$${θ}_{conducteur} = \frac{( {θ}_{b 1} {T}_{b} - {θ}_{b 1}^{′} {T}_{b}^{′} ) \times ( ( {θ}_{b 1} - {θ}_{b 2} ) )}{{T}_{b} ( {θ}_{b 1}^{′} - {θ}_{b 2}^{′} ) - {T}_{b}^{′} ( {θ}_{b 1} - {θ}_{b 2} )}$$
where T₁ is the thermal resistance of said at least one layer of material,
T_{b} is the first additional thermal resistance of the first additional layer of material,
T′_{b} is the second additional thermal resistance of the second additional layer of material,
Θ_{b1} is the peripheral temperature measured by said at least one first temperature sensor,
Θ_{b2} is the additional peripheral temperature measured by said at least one first additional temperature sensor,
Θ′_{b1} is the peripheral temperature measured by said at least one second temperature sensor,
Θ′_{b2} is the additional peripheral temperature measured by said at least one second additional temperature sensor.

8. The determination system according to claim 4, wherein the first and second additional-layer portions are made of a different material.

9. The determination system according to claim 4, wherein the first and second additional-layer portions have a different thickness, considered perpendicularly in relation to a longitudinal axis of extent of the electric cable.

10. The determination system according to claim 1, wherein said at least one layer of material comprises an outer sheath forming said outer surface, said at least one temperature sensor being placed on said outer sheath.

11. The determination system according to claim 1, wherein the determination unit is configured to determine the conductor temperature Θ_{cond} as a function of the heat flux W_{c} generated by the flow of an electrical current in the electrical conductor, on the basis of the following equation:
$${θ}_{cond} = {θ}_{b 1} + {W}_{c} * {T}_{1}$$

12. The determination system according to claim 1, further comprising a device for measuring the electrical intensity I_{cond} of an electrical current flowing in said at least one electrical conductor, the determination unit being configured to determine said conductor temperature Θ_{cond} also as a function of this electrical intensity I_{cond}.

13. The determination system according to claim 12, wherein the measuring device is a non-invasive device, in particular of the Rogowski coil type.

14. The determination system according to claim 12, wherein the conductor temperature Θ_{cond} is determined as follows:
$${θ}_{cond} = {θ}_{b 1} + {R}_{c} * {I}_{cond}^{2} * {T}_{1}$$
where R_{c} is the electrical resistance of the conductor,
I_{cond} is the electrical current flowing in said at least one electrical conductor.

15. The determination system according to claim 2, wherein said additional layer of material extends around said at least one layer of material only over a portion of the length of the electric cable.

16. The determination system according to claim 2, wherein the determination unit is configured to determine the conductor temperature Θ_{cond} on the basis of the following equation:
$${θ}_{cond} = {θ}_{b 1} + \frac{( {θ}_{b 1} - {θ}_{b 2} )}{{T}_{b}} \times {T}_{1}$$
where Θ_{b1} is the peripheral temperature measured by said at least one temperature sensor,
Θ_{b2} is the additional peripheral temperature measured by said at least one additional temperature sensor,
T_{b} is the additional thermal resistance of the additional layer of material,
T₁ is the thermal resistance of said at least one layer of material.

17. The determination system according to claim 1, wherein the determination unit is configured to determine the conductor temperature Θ_{cond} also as a function of a heating W_{d} originating from a dielectric loss in said at least one layer of material.

18. The determination system according to claim 12, wherein the determination unit is configured to determine the conductor temperature Θ_{cond} also as a function of a heating W_{d} originating from a dielectric loss in said at least one layer of material, and
wherein the determination unit is configured to determine the conductor temperature Θ_{cond} on the basis of the following equation:
$${θ}_{cond} = {θ}_{b 1} + {T}_{1} \times ( {W}_{c} + \frac{{W}_{d}}{2} )$$
where W_{d} is the heating originating from a dielectric loss in said at least one layer of material.

19. The determination system according to claim 2, wherein the determination unit is configured to determine the conductor temperature Θ_{cond} also as a function of a heating W_{d} originating from a dielectric loss in said at least one layer of material, and
wherein the determination unit is configured to determine the conductor temperature Θ_{cond} on the basis of the following equation:
$${θ}_{cond} = {θ}_{b 1} + {T}_{1} \times ( \frac{{θ}_{b 1} - {θ}_{b 2}}{{T}_{b}} - \frac{{W}_{d}}{2} )$$
where W_{d} is the heating originating from a dielectric loss in said at least one layer of material.

20. The determination system according to claim 1, further comprising a determination module comprising one or more of the following: said at least one temperature sensor and the determination unit, the module being configured to be removably mounted on the electric cable.

21. The determination system according to 20, the determination system further comprising:
at least one additional layer of material placed around said at least one layer of material and covering said at least one temperature sensor, said additional layer of material having an additional thermal resistance T_{b},
at least one additional temperature sensor placed on an outer surface of said additional layer of material for measuring an additional peripheral temperature Θ_{b2} on the outer surface of said at least one additional layer of material, and
wherein said at least one additional layer of material and said at least one additional temperature sensor are supported by the determination module.
